(19) United States
(12) Patent Application Publication
(10) Pub. No.: US 2019/0189912 A1
(43) Pub. Date: Jun. 20, 2019

(54) Structures Enabling Voltage Control of Oxidation Within Magnetic Heterostructures

(71) Applicant: Inston Inc., Santa Monica, CA (US)

(72) Inventor: Farbod Ebrahimi, Santa Monica, CA (US)

(73) Assignee: Inston Inc., Santa Monica, CA (US)

(21) Appl. No.: 16/228,328

(22) Filed: Dec. 20, 2018

Related U.S. Application Data
(60) Provisional application No. 62/608,512, filed on Dec. 20, 2017.

(51) Int. Cl. H01L 43/10; H01L 43/02

(52) U.S. Cl. CPC H01L 43/10; H01L 27/222; H01L 43/02

(57) ABSTRACT

In many embodiments, Gd/GdO materials are incorporated into a magnetic heterostructure between the electrodes, either in contact with the electrodes or within the stack of the heterostructure. In some embodiments, the Gd/GdO materials can be inserted into a single magnetic layer. In several embodiments, the Gd/GdO materials can be inserted within a magnetic tunnel junction stack, i.e., a magnetic structure that includes two ferromagnetic layers separated by an insulating layer. In further embodiments, the Gd/GdO materials are utilized in voltage-controlled magnetic anisotropy-based MTJs (“VMTJs”), which are devices that uses the voltage-controlled magnetic anisotropy (“VCMA”) phenomena to reduce the coercivity of the free layer of the VMTJs to make the free layer more easily switched to the opposite direction (writeable). Gd/GdO materials can also be utilized within a magnetoelectric junction (“MEJ”) structure.

### CROSS-REFERENCE TO RELATED APPLICATIONS

The current application claims the benefit of and priority under 35 U.S.C. § 119(e) to U.S. Provisional Patent Application No. 62/608,512 entitled “Structures Enabling Voltage Control of Oxidation Within Magnetic Heterostructures,” filed Dec. 20, 2017. The disclosure of U.S. Provisional Patent Application No. 62/608,512 is hereby incorporated by reference in its entirety for all purposes.

### FIELD OF THE INVENTION

The present invention generally relates to materials allowing for the manipulation of the magnetic properties of magnetic heterostructures and heterostructures made using such materials.

### BACKGROUND

Devices that rely on electricity and magnetism underlie much of modern electronics. Researchers have recently begun to develop and implement devices that take advantage of both electricity and magnetism in spin-electronic (or so-called “spintronic”) devices. These devices utilize quantum-mechanical magnetoresistance effects, such as giant magnetoresistance (“GMR”) and tunnel magnetoresistance (“TMR”). GMR and TMR principles regard how the resistance of a thin film structure that includes alternating layers of ferromagnetic and non-magnetic layers depends upon whether the magnetizations of ferromagnetic layers are in a parallel or antiparallel alignment. For example, magnetoresistive random-access memory (“MRAM”) is a technology that is being developed that typically utilizes TMR phenomena in providing for alternative random-access memory (“RAM”) devices. In a typical MRAM bit, data is stored in a magnetic structure that includes two ferromagnetic layers separated by an insulating layer—this structure is conventionally referred to as a magnetic tunnel junction (“MTJ”). The magnetization of one of the ferromagnetic layers (the fixed layer) is permanently set to a particular direction, while the other ferromagnetic layer (the free layer) can have its magnetization direction free to change. Generally, the MRAM bit can be written by manipulating the magnetization of the free layer such that it is either parallel or antiparallel with the magnetization of the fixed layer; and the bit can be read by measuring its resistance (since the resistance of the bit will depend on whether the magnetizations are in a parallel or antiparallel alignment).

MRAM technologies initially exhibited a number of technological challenges. The first generation of MRAM utilized the Oersted field generated from current in adjacent metal lines to write the magnetization of the free layer, which required a large amount of current to manipulate the magnetization direction of the bit's free layer when the bit size shrinks down to below 100 nm. Thermal assisted MRAM (“TA-MRAM”) utilizes heating of the magnetic layers in the MRAM bits above the magnetic ordering temperature to reduce the write field. This technology also requires high power consumption and long wire cycles. Spin transfer torque MRAM (“STT-MRAM”) utilizes the spin-polarized current exerting torque on the magnetization direction in order to reversibly switch the magnetization direction of the free layer.

### SUMMARY OF THE INVENTION

One embodiment includes a magnetic heterostructure including at least two electrodes, a plurality of magnetic layers disposed between the at least two electrodes, wherein an insulating layer is disposed between at least two magnetic layers, and at least one material layer disposed between the at least two electrodes, wherein the at least one material layer includes a material selected from the group of Gd, GdO, and hybrids thereof.

In another embodiment, the at least one material layer is disposed adjacent to at least one of the plurality of magnetic layers and the insulating layer.

In a further embodiment the at least one material layer is disposed between two of the plurality of magnetic layers and the insulating layer.

In still another embodiment, the at least one material layer is configured to modify at least one magnetic property of the magnetic heterostructure.

In a still further embodiment, the at least one material layer is configured to control the oxygen concentration in adjacent layers in response to an applied electric field.

A yet another embodiment includes a magnetic tunnel junction including a plurality of magnetic layers, wherein an insulating layer is disposed between at least two of the magnetic layers, and wherein at least one of the magnetic layers is a reference layer and one of the magnetic layers is a free layer, and at least one material layer including a material selected from the group of Gd, GdO, and hybrids thereof.

In a yet further embodiment, the at least one material layer is disposed on one or both sides of the reference layer.

In another additional embodiment, the at least one material layer is disposed between the reference and insulating layers.

In a further additional embodiment, at least one of the magnetic layers is a pinning layer, and the at least one material layer is disposed between the reference layer and the pinning layer.

In another embodiment again, the at least one material layer is disposed adjacent to the free layer.

In a further embodiment again, the at least one material layer is disposed between the free layer and the insulating layer.

In still yet another embodiment, the at least one material layer is configured to modify at least one magnetic property of the magnetic heterostructure.

In a still yet further embodiment, the at least one material layer is configured to control the oxygen concentration in adjacent layers in response to an applied electric field.

### BRIEF DESCRIPTION OF THE DRAWINGS

The description will be more fully understood with reference to the following figures and data graphs, which are presented as exemplary embodiments of the invention and should not be construed as a complete recitation of the scope of the invention.

FIG. 1A conceptually illustrates an MEJ whereby the FM fixed layer and the FM free layer are separated by, and directly adjoined to, a dielectric layer in accordance with an embodiment of the invention.

FIG. 1B conceptually illustrates an MEJ with constituent cap/seed layers in accordance with an embodiment of the invention.

FIG. 2 conceptually illustrates an MEJ whereby the orientation of the magnetization directions is perpendicular to the plane of the constituent layers in accordance with an embodiment of the invention.

FIG. 3 conceptually illustrates an MEJ that includes multiple layers that work in aggregate to facilitate the functionality of the MEJ in accordance with an embodiment of the invention.

FIGS. 4A and 4B conceptually illustrate MEJs that include a semi-fixed layer in accordance with various embodiments of the invention.

FIGS. 5A and 5B conceptually illustrate how the application of a potential difference can reduce the coercivity of the free layer in accordance with various embodiments of the invention.

FIG. 6 conceptually illustrates using a metal line disposed adjacent to an FM free layer to generate spin-orbit torques that can impose a magnetization direction change on the FM free layer in accordance with an embodiment of the invention.

FIG. 7 conceptually illustrates the implementation of two MEJs that are housed within encapsulating layers and separated by field insulation in accordance with an embodiment of the invention.

FIG. 8A and 8B conceptually illustrate schematics of magnetic heterostructures incorporating Gd/GdO materials in accordance with various embodiments of the invention.

FIG. 9 conceptually illustrates a schematic of a magnetic tunnel junction in accordance with an embodiment of the invention.

FIGS. 10A and 10B conceptually illustrate schematics of magnetic tunnel junctions incorporating Gd/GdO materials in accordance with various embodiments of the invention.

### DETAILED DESCRIPTION

Turning now to the drawings, magnetic heterostructures and magnetic layers incorporating materials for voltage control of oxidation are provided. In many magnetic heterostructures, an oxide layer is typically used within the film stack for a variety of reasons, including but not limited to, as a tunneling barrier, seed layer towards the promotion of specific crystallinity, etc. At the interface between the metallic ferromagnet (“FM”) and oxide material, the FM will usually see some oxygen diffusion, which can change the properties of the FM, most notably varying its magnetization strength (also referred to as its coercivity). In various embodiments, materials such as gadolinium (Gd) and/or gadolinium oxide (GdO) are incorporated into magnetic heterostructures and magnetic layers.

In many embodiments, Gd/GdO materials are incorporated into a magnetic heterostructure between the electrodes, either in contact with the electrodes or within the stack of the heterostructure. In some embodiments, the Gd/GdO materials can be inserted into a single magnetic layer. In several embodiments, the Gd/GdO materials can be inserted within a magnetic tunnel junction stack, i.e., a magnetic structure that includes two ferromagnetic layers separated by an insulating layer. In further embodiments, the Gd/GdO materials are utilized in voltage-controlled magnetic anisotropy-based MTJs (“VMTJs”), which are devices that uses the voltage-controlled magnetic anisotropy (“VCMA”) phenomena to reduce the coercivity of the free layer of the VMTJs to make the free layer more easily switched to the opposite direction (writeable). Gd/GdO materials can also be utilized within a magnetoelectric junction (“MEJ”) structure. In this disclosure, the term “magnetoelectric junction” is used to refer to devices that are configured to viably use VCMA principles to help them realize two distinct information states—e.g., voltage-controlled magnetic anisotropy-based MTJs (“VMTJs”) and VCMA switches.

Gd/GdO materials can be used to modify various magnetic properties of the heterostructures and layers, including but not limited to: saturation magnetization, steady-state magnetic orientation, magnetic strength, magnetic coercivity, antiferro/ferro/ferri/superpara/para/dia-magnetism, conductivity, voltage sensitivity of the voltage controlled magnetic anisotropy effect, perpendicular magnetic anisotropy, etc. MTJs, MEJs, and the use of Gd/GdO materials in magnetic heterostructures and magnetic layers are discussed below in further detail.

### Fundamental Magnetoelectric Junction Structures

A fundamental MEJ structure typically includes a ferromagnetic fixed layer, a FM free layer that has a uniaxial anisotropy (for simplicity, the terms “FM fixed layer” and “fixed layer” will be considered equivalent throughout this application, unless otherwise stated; similarly, the terms “FM free layer”, “ferromagnetic free layer,” “free layer that has a uniaxial anisotropy”, and “free layer” will also be considered equivalent throughout this application, unless otherwise stated), and a dielectric layer separating the FM fixed layer and FM free layer. Generally, the FM fixed layer has a fixed magnetization direction—i.e., the direction of magnetization of the FM fixed layer does not change during the normal operation of the MEJ. Conversely, the FM free layer can adopt a magnetization direction that is either substantially parallel with or antiparallel with the FM fixed layer—i.e., during the normal operation of the MEJ, the direction of magnetization can be made to change. For example, the FM free layer may have a magnetic uniaxial anisotropy, whereby it has an easy axis that is substantially aligned with the direction of magnetization of the FM fixed layer. The easy axis refers to the axis, along which the magnetization direction of the layer prefers to align. In other words, an easy axis is an energetically favorable direction (axis) of spontaneous magnetization that is determined by various sources of magnetic anisotropy including, but not limited to, magnetocrystalline anisotropy, magnetoelastic anisotropy, geometric shape of the layer, etc. Relatedly, an easy plane is a plane whereby the direction of magnetization is favored to be within the plane, although there is no bias toward a particular axis within the plane. The easy axis and the direction of the magnetization of the fixed layer can be considered to be ‘substantially aligned’ when—in the case where the magnetization direction of the free layer conforms to the easy axis—the underlying principles of magnetoresistance take effect and result in a distinct measurable difference in the resistance of the MEJ as between when the magnetization directions of the FM layers are substantially parallel relative to when they are substantially antiparallel, e.g. such that two distinct information states can be defined. Similarly, the magnetization directions of the fixed layer and the free layer can be considered to be substantially parallel/antiparallel when the underlying principles of magnetoresistance take effect and result in a distinct measurable difference in the resistance of the MEJ as between the two states (i.e., substantially parallel and substantially antiparallel).

VCMA phenomena can be relied on in switching the FM free layer's characteristic magnetization direction—i.e., the MEJ can be configured such that the application of a potential difference across the MEJ can reduce the coercivity of the free layer, which can allow the free layer's magnetization direction to be switched more easily. For example, with a reduced coercivity, the FM free layer can be subject to magnetization that can make it substantially parallel with or substantially antiparallel with the direction of the magnetization for the FM fixed layer. A more involved discussion regarding the general operating principles of an MEJ is presented in the following section.

Notably, the magnetization direction, and the related characteristics of magnetic anisotropy, can be established for the FM fixed and FM free layers using any suitable method. For instance, the shapes of the constituent FM fixed layer, FM free layer, and dielectric layer, can be selected based on desired magnetization direction orientations. For example, implementing FM fixed, FM free, and dielectric layers that have an elongated shape (e.g., an elliptical cross-section) may tend to induce magnetic anisotropy that is in the direction of the length of the elongated axis—i.e., the FM fixed and FM free layers will possess a tendency to adopt a direction of magnetization along the length of the elongated axis. In other words, the direction of the magnetization is ‘in-plane’. Alternatively, where it is desired that the magnetic anisotropy have a directional component that is perpendicular to the FM fixed and FM free layers (i.e., ‘out-of-plane’), the shape of the layers can be made to be symmetrical, e.g. circular, and further the FM layers can be made to be thin. In this case, while the tendency of the magnetization to remain in-plane may still exist, it may not have a preferred directionality within the plane of the layer. Because the FM layers are relatively thinner, the anisotropic effects that result from interfaces between the FM layers and any adjacent layers, which tend to be out-of-plane, may tend to dominate the overall anisotropy of the FM layer. Alternatively, a material may be used for the FM fixed or free layers which has a bulk perpendicular anisotropy—i.e., an anisotropy originating from its bulk (volume) rather than from its interfaces with other adjacent layers. The FM free or fixed layers may also consist of a number of sub-layers, with the interfacial anisotropy between individual sub-layers giving rise to an effective bulk anisotropy to the material as a whole. Additionally, FM free or fixed layers may be constructed which combine these effects, and for example have both interfacial and bulk contributions to perpendicular anisotropy. Of course, any suitable methods for imposing magnetic anisotropy can be implemented in accordance with many embodiments of the invention.

While MEJs demonstrate much promise, their potential applications continue to be explored. For example, U.S. Pat. No. 8,841,739 to Khalili Amiri et al. discloses DIOMEJ cells that utilize diodes (e.g. as opposed to transistors) as access devices to MEJs. As discussed in the '739 patent, using diodes as access devices for MEJs can confer a number of advantages and thereby make the implementation of MEJs much more practicable. The disclosure of U.S. Pat. No. 8,841,739 is hereby incorporated by reference in its entirety, especially as it pertains to implementing diodes as access devices for MEJs. Furthermore, U.S. Pat. No. 9,099,641 to Khalili Amiri et al. discloses MEJ configurations that demonstrate improved writeability and readability, and further make the implementation of MEJs more practicable. The disclosure of U.S. Pat. No. 9,099,641 is hereby incorporated by reference in its entirety, especially as it pertains to MEJ configurations that demonstrate improved writeability and readability. Additionally, U.S. patent application Ser. No. 14/681,358 to Qi Hu discloses implementing MEJ configurations that incorporate piezoelectric materials to strain the respective MEJs during operation, and thereby improve performance. The disclosure of U.S. patent application Ser. No. 14/681,358 is hereby incorporated by reference in its entirety, especially as it pertains to MEJ configurations that incorporate elements configured to strain the respective MEJs during operation, and thereby improve performance.

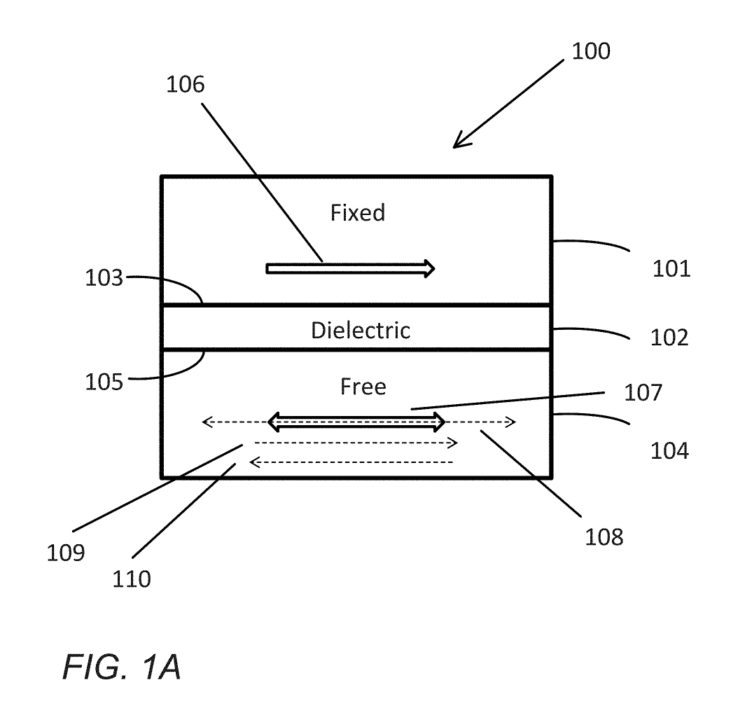

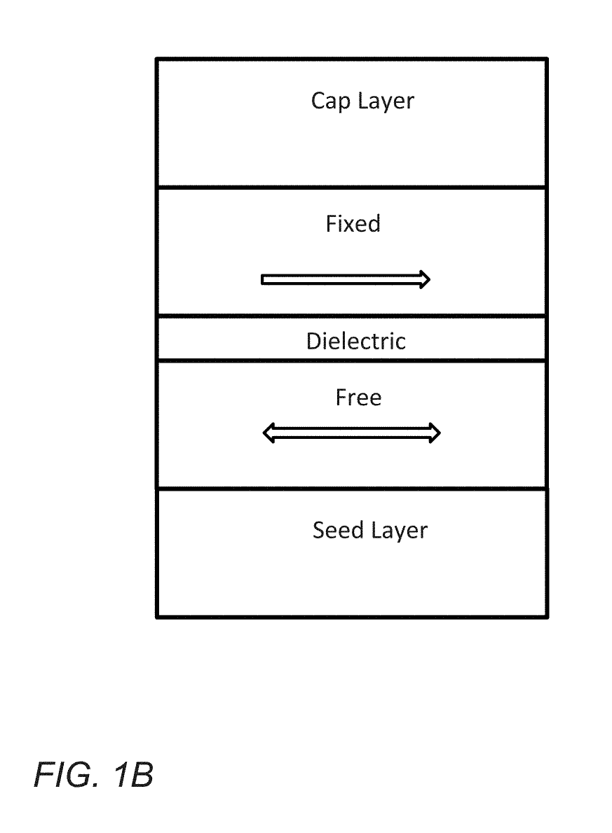

FIG. 1A conceptually illustrates an MEJ whereby the FM fixed layer and the FM free layer are separated by, and directly adjoined to, a dielectric layer. In particular, in the illustration, the MEJ 100 includes an FM fixed layer 101 that is adjoined to a dielectric layer 102, thereby forming a first interface 103; the MEJ further includes an FM free layer 104 that is adjoined to the dielectric layer 102 on an opposing side of the first interface 103, and thereby forms a second interface 105. The MEJ 100 has an FM fixed layer 101 that has a magnetization direction 106 that is in-plane, and depicted in the illustration as being from left to right. Accordingly, the FM free layer is configured such that it can adopt a magnetization direction 107 that is either parallel with or antiparallel with the magnetization direction of the FM fixed layer. For reference, the easy axis 108 is illustrated, as well as a parallel magnetization direction 109, and an antiparallel magnetization direction 110. Additional contacts (capping or seed materials, or multilayers of materials, not shown in FIG. 1A) may be attached to the FM free layer 104 and the FM fixed layer 101, thereby forming additional interfaces. FIG. 1B conceptually illustrates an MEJ and depicts the constituent cap/seed layers. The contacts can both contribute to the electrical and magnetic characteristics of the device by providing additional interfaces, and can also be used to apply a potential difference across the device. Additionally, it should of course be understood that MEJs can include metallic contacts that can allow them to interconnect with other electrical components.

Importantly, by appropriately selecting the materials, the MEJ can be configured such that the application of a potential difference across the FM fixed layer and the FM free layer can modify the magnetic anisotropy, and correspondingly reduce the coercivity, of the FM free layer. For example, whereas in FIGS. 1A and 1B, the magnetization direction of the FM free layer is depicted as being in-plane, the application of a voltage may distort the magnetization direction of the FM free layer such that it includes a component that is at least partially out of plane. The particular dynamics of the modification of the magnetic anisotropy will be discussed below in the section entitled “General Principles of MEJ Operation.” Suitable materials for the FM layers such that this effect can be implemented include iron, nickel, manganese, cobalt, FeCoB, FeGaB, FePd, FePt; further, any compounds or alloys that include these materials may also be suitable. Suitable materials for the dielectric layer include MgO and Al₂O₃. Of course, it should be understood that the material selection is not limited to those recited—any suitable FM material can be used for the FM fixed and free layers and any suitable material can be used for the dielectric layer. It should also be understood that each of the FM free layer, FM fixed layer, and dielectric layer may consist of a number of sub-layers, which acting together provide the functionality of the respective layer.

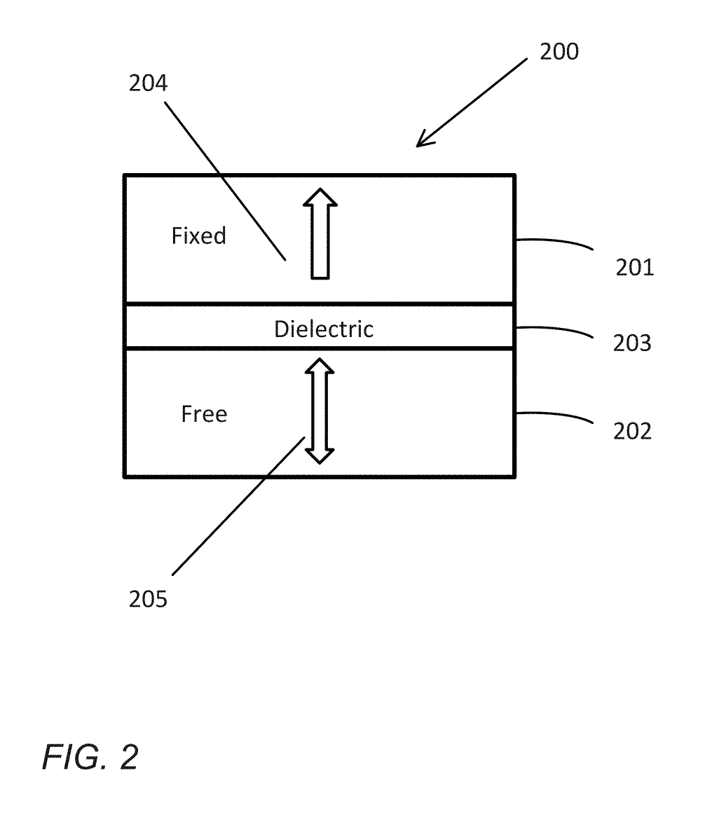

FIG. 2 conceptually illustrates an MEJ whereby the orientation of the magnetization directions is perpendicular to the plane of the constituent layers (“perpendicular magnetic anisotropy”). In particular, the MEJ 200 is similarly configured to that seen in FIG. 1A, with an FM fixed layer 201 and an FM free layer 202 adjoined to a dielectric layer 203. However, unlike the MEJ in FIG. 1A, the magnetization directions of the FM fixed and FM free layers, 204 and 205 respectively, are oriented perpendicularly to the layers of the MEJ. Additional contacts (capping or seed materials, or multilayers of materials, not shown) may be attached to the FM free layer 202 and the FM fixed layer 201, thereby forming additional interfaces. The contacts both contribute to the electrical and magnetic characteristics of the device by providing additional interfaces, and can also be used to apply a potential difference across the device. It should also be understood that each of the FM free layer, FM fixed layer, and dielectric layer may consist of a number of sub-layers, which acting together provide the functionality of the respective layer.

Of course, it should be understood that the direction of magnetization for the FM layers can be in any direction, as long as the FM free layer can adopt a direction of magnetization that is either substantially parallel with or antiparallel with the direction of magnetization of the FM fixed layer. For example, the direction of magnetization can include both in-plane and out-of-plane components.

In many instances, an MEJ includes additional adjunct layers that function to facilitate the operation of the MEJ. For example, in many instances, the FM free layer includes a capping or seed layer, which can (1) help induce greater electron spin perpendicular to the surface of the layer, thereby increasing its perpendicular magnetic anisotropy, and/or (2) can further enhance the sensitivity to the application of an electrical potential difference. In general, the seed/cap layers can beneficially promote the crystallinity of the ferromagnetic layers. The seed layer can also serve to separate a corresponding ferromagnetic layer from an ‘underlayer.’ As will be discussed below, in many embodiments of the invention, the capping/seed layer includes one of: Hf, Mo, W, Ir, Bi, Re, and/or Au; the listed elements can be incorporated by themselves, in combination with one another, or in combination with more conventional materials, such as Ta, Ru, Pt, Pd. As will be discussed in greater detail below, seed and/or cap layers made in this way can confer a number of benefits to the MEJ structure.

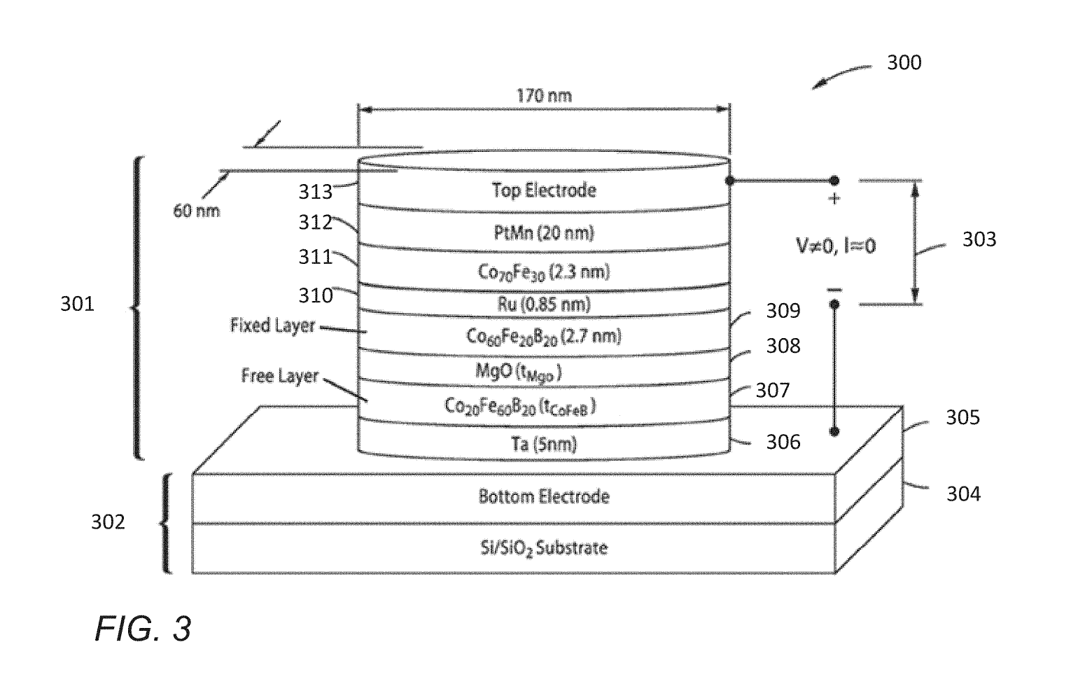

FIG. 3 conceptually illustrates an MEJ 300 that includes multiple layers that work in aggregate to facilitate the functionality of the MEJ 300. A pillar section 301 extends from a planar section 302. A voltage is shown being applied 303 between the top and bottom of the pillar. By way of example, the planar section 302 includes an Si/SiO₂ substrate 304 adjoined to a bottom electrode 305. In the illustrated embodiment, the pillar 301 includes the following layers in order: Ta 306 (e.g., 5 nm in thickness); a free layer 307 having an Fe-rich CoFeB material (e.g., Co₂₀Fe₆₀B₂₀ having a thickness generally ranging from, but not limited to, 0.8 nm-1.6 nm); a dielectric layer 308 having a dielectric oxide such as MgO or Al₂O₃ having a thickness of approximately, but not limited to, 0.8-1.4 nm); a FM fixed layer 309 having a CoFeB material (e.g., Co₆₀Fe₂₀B₂₀ having a thickness of approximately, but not limited to, 2.7 nm); a metal layer (e.g. Ru 310 having a thickness of approximately, but not limited to, 0.85 nm) to provide antiferromagnetic inter-layer exchange coupling; an exchange-biased layer 311 of Co₇₀Fe₃₀ (e.g., thickness of approximately, but not limited to, 2.3 nm), the magnetization orientation of which is pinned by exchange bias using an anti-ferromagnetic layer 312 (e.g., PtMn, IrMn, or a like material having a thickness of approximately, but not limited to, 20 nm); and a top electrode 313. By way of example and not limitation, the pillar of the device depicted is in the shape of a 170 nm×60 nm elliptical nanopillar. In this illustration, Ta layer 306 is used as a seed layer to help induce a larger magnitude of perpendicular magnetic anisotropy and/or enhance the electric-field sensitivity of magnetic properties (such as anisotropy) in the FM free layer. It also acts as a sink of B atoms during annealing of the material stack after deposition, resulting in better crystallization of the FM free layer and thereby increasing the TMR and/or VCMA effect. Of course, any suitable materials can be used as a capping or seed layer 306; for example, as will be discussed in greater detail below, in many embodiments of the invention, the seed and/or cap layers include one of: Mo, W, Hf, Ir, Bi, Rh, and/or Au. More generally, any adjunct layers that can help facilitate the proper functioning of the MEJ can be implemented in an MEJ.

MEJs can also include a semi-fixed layer, which has a magnetic anisotropy that is altered by the application of a potential difference. In many instances, the characteristic magnetic anisotropy of the semi-fixed layer is a function of the applied voltage. For example, in many cases, the direction of the magnetization of the semi-fixed layer is oriented in the plane of the layer in the absence of a potential difference across the MEJ. However, when a potential difference is applied, the magnetic anisotropy is altered such that the magnetization includes a strengthened out-of-plane component. Moreover, the extent to which the magnetic anisotropy of the semi-fixed layer is modified as a function of applied voltage can be made to be less than the extent to which the magnetic anisotropy of the FM free layer is modified as a function of applied voltage. The incorporation of a semi-fixed layer can facilitate a more nuanced operation of the MEJ (to be discussed below in the section entitled “General Principles of MEJ Operation”).

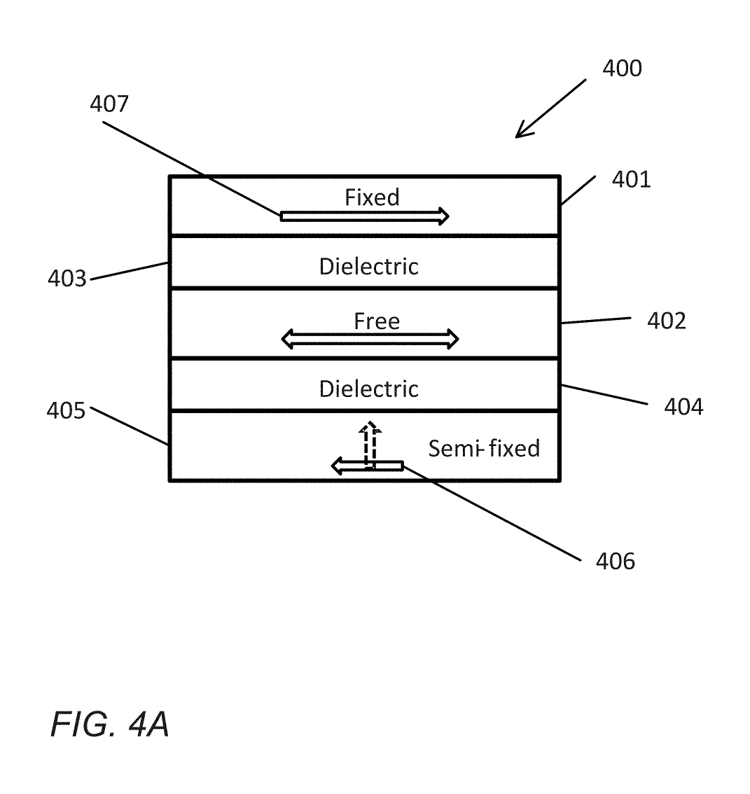

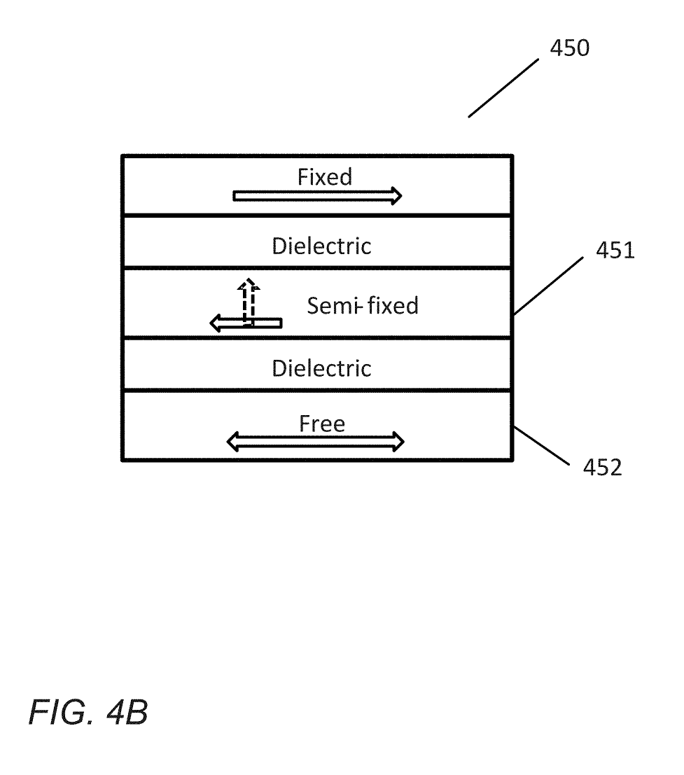

FIG. 4A conceptually illustrates an MEJ that includes a semi-fixed layer in accordance with an embodiment of the invention. In particular, the configuration of the MEJ 400 is similar to that depicted in FIG. 1A, insofar as it includes an FM fixed layer 401 and an FM free layer 402 separated by a dielectric layer 403. However, the MEJ 400 further includes a second dielectric layer 404 adjoined to the FM free layer 402 such that the FM free layer 402 is adjoined to two dielectric layers, 403 and 404 respectively, on opposing sides. Further, a semi-fixed layer 405 is adjoined to the dielectric layer. Typically, the direction of magnetization of the semi-fixed layer 406 is antiparallel with that of the FM fixed layer 407. As mentioned above, the direction of magnetization of the semi-fixed layer can be manipulated based on the application of a voltage. In the illustration, it is depicted that the application of a potential difference adjusts the magnetic anisotropy of the semi-fixed layer such that the strength of the magnetization along a direction orthogonal to the initial direction of magnetization (in this case, out of the plane of the layer) is developed. It should of course be noted that the application of a potential difference can augment the magnetic anisotropy in any number of ways; for instance, in some MEJs, the application of a potential difference can reduce the strength of the magnetization in a direction orthogonal to the initial direction of magnetization. Note also that in the illustration, the directions of magnetization are all depicted to be in-plane where there is no potential difference. However, of course it should be understood that the direction of the magnetization can be in any suitable direction. More generally, although a particular configuration of an MEJ that includes a semi-fixed layer is depicted, it should of course be understood that a semi-fixed layer can be incorporated within an MEJ in any number of configurations. For example, FIG. 4B conceptually illustrates an MEJ that includes a semi-fixed layer that is in a different configuration than that seen in 4A. In particular, the MEJ 450 is similar to that seen in FIG. 4A, except that the positioning of the semi-fixed layer 451 and the free layer 452 is inverted. In certain situations, such a configuration may be more desirable. The general principles of the operation of an MEJ are now discussed.

### General Principles of MEJ Operation

MEJ operating principles—as they are currently understood—are now discussed. Note that embodiments of the invention are not constrained to the particular realization of these phenomena. Rather, the presumed underlying physical phenomena is being presented to inform the reader as to how MEJs are believed to operate. MEJs generally function to achieve two distinct states using the principles of magnetoresistance. As mentioned above, magnetoresistance principles regard how the resistance of a thin film structure that includes alternating layers of ferromagnetic and non-magnetic layers depends upon whether the ferromagnetic layers are in a substantially parallel or antiparallel alignment. Thus, an MEJ can achieve a first state where its FM layers have magnetization directions that are substantially parallel, and a second state where its FM layers have magnetization directions that are substantially antiparallel. MEJs further rely on voltage-controlled magnetic anisotropy phenomena. Generally, VCMA phenomena regard how the application of a voltage to a ferromagnetic material that is adjoined to an adjacent dielectric layer can impact the characteristics of the ferromagnetic material's magnetic anisotropy. For example, it has been demonstrated that the interface of oxides such as MgO with metallic ferromagnets such as Fe, CoFe, and CoFeB can exhibit a large perpendicular magnetic anisotropy which is furthermore sensitive to voltages applied across the dielectric layer, an effect that has been attributed to spin-dependent charge screening, hybridization of atomic orbitals at the interface, and to the electric field induced modulation of the relative occupancy of atomic orbitals at the interface. MEJs can exploit this phenomenon to achieve two distinct states. For example, MEJs can employ one of two mechanisms to do so: first, MEJs can be configured such that the application of a potential difference across the MEJ functions to reduce the coercivity of the FM free layer, such that it can be subject to magnetization in a desired magnetic direction, e.g. either substantially parallel with or antiparallel with the magnetization direction of the fixed layer; second, MEJ operation can rely on precessional switching (or resonant switching), whereby by precisely subjecting the MEJ to voltage pulses of precise duration, the direction of magnetization of the FM free layer can be made to switch.

In many instances, MEJ operation is based on reducing the coercivity of the FM free layer such that it can adopt a desired magnetization direction. With a reduced coercivity, the FM free layer can adopt a magnetization direction in any suitable way. For instance, the magnetization can result from: an externally applied magnetic field, the magnetic field of the FM fixed layer; the application of a spin-transfer torque (“STT”) current; the magnetic field of a FM semi-fixed layer; the application of a current in an adjacent metal line inducing a spin-orbit torque (“SOT”); and any combination of these mechanisms, or any other suitable method of magnetizing the FM free layer with a reduced coercivity.

By way of example and not limitation, examples of suitable ranges for the externally applied magnetic field are in the range of 0 to 100 Oe. The magnitude of the electric field applied across the device to reduce its coercivity or bring about resonant switching can be approximately in the range of 0.1-2.0 V/nm, with lower electric fields required for materials combinations that exhibit a larger VCMA effect. The magnitude of the STT current used to assist the switching may be in the range of approximately 0.1-1.0 MA/cm².

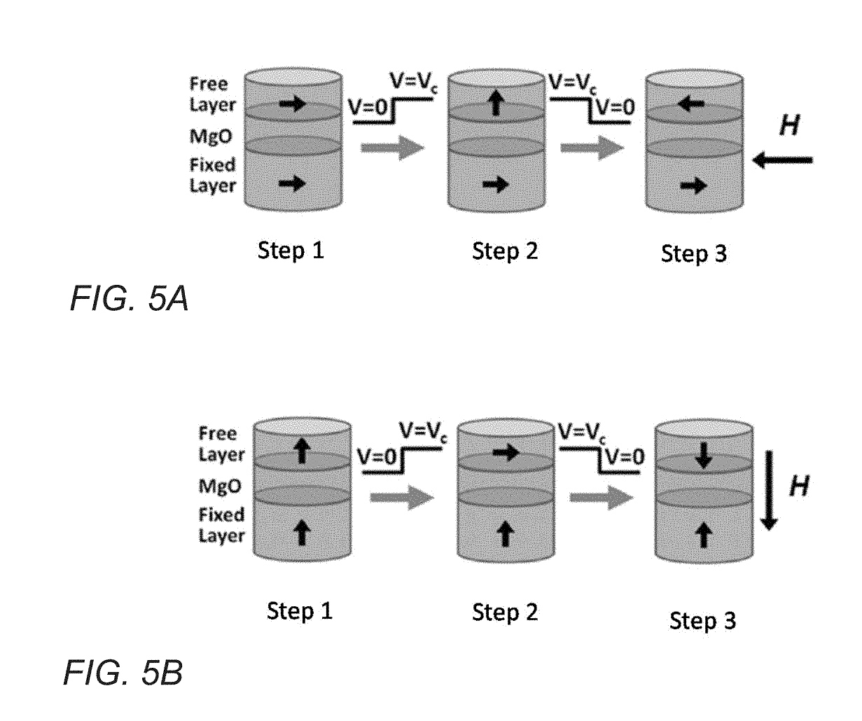

FIG. 5A depicts how the application of a potential difference can reduce the coercivity of the free layer such that an externally applied magnetic field H can impose a magnetization switching on the free layer. In the illustration, in step 1, the FM free layer and the FM fixed layer have a magnetization direction that is substantially in plane; the FM free layer has a magnetization direction that is parallel with that of the FM fixed layer. Further, in Step 1, the coercivity of the FM free layer is such that the FM free layer is not prone to having its magnetization direction reversed by the magnetic field H, which is in a direction antiparallel with the magnetization direction of the FM fixed layer. However, a voltage V_{c}, is then applied, which results in step 2, where the voltage V_{c}, has magnified the perpendicular magnetization direction component of the free layer (out of its plane). Correspondingly, the coercivity of the FM free layer is reduced such that it is subject to magnetization by an in-plane magnetic field H. Accordingly, when the potential difference V_{c}, is removed, VCMA effects are removed and the magnetic field H, which is substantially anti-parallel to the magnetization direction of the FM fixed layer, causes the FM free layer to adopt a direction of magnetization that is antiparallel with the magnetization direction of the FM fixed layer. Hence, as the MEJ now includes an FM fixed layer and an FM free layer that have magnetization directions that are antiparallel, it reads out a second information state (resistance value) different from the first. In general, it should be understood that in many embodiments where the magnetization directions of the free layer and the fixed layer are substantially in-plane, the application of a voltage enhances the perpendicular magnetic anisotropy such that the FM free layer can be caused to adopt an out-of-plane direction of magnetization. Stated differently, the magnetoelectric junction is configured such that when a potential difference is applied across the magnetoelectric junction, the magnetic anisotropy of the ferromagnetic free layer is altered such that the relative strength of the magnetic anisotropy along a second easy axis that is orthogonal to the first easy axis (which corresponds to the magnetization direction of the fixed layer), or the easy plane where there is no easy axis that is orthogonal to the first easy axis, as compared to the strength of the magnetic anisotropy along the first easy axis, is magnified or reduced for the duration of the application of the potential difference. The magnetization direction can thereby be made to switch. In general, it can be seen that by controlling the potential difference and the direction of an applied external magnetic field, an MEJ switch can be achieved.

It should of course be understood that the direction of the FM fixed layer's magnetization direction need not be in-plane—it can be in any suitable direction. For instance, it can be substantially out of plane. Additionally, the FM free layer can include both in-plane and out-of-plane magnetic anisotropy directional components. FIG. 5B depicts a corresponding case relative to FIG. 5A when the FM fixed and FM free layers have magnetization directions that are perpendicular to the layers of the MEJ (out-of-plane). It is of course important, that an FM, magnetically anisotropic, free layer be able to adopt a magnetization direction that is either substantially parallel with an FM fixed layer, or substantially antiparallel with an FM fixed layer. In other words, when unburdened by a potential difference, the FM free layer can adopt a direction of magnetization that is either substantially parallel with or antiparallel with the direction of the FM fixed layer's magnetization, to the extent that a distinct measurable difference in the resistance of the MEJ that results from the principles of magnetoresistance as between the two states (i.e., parallel alignment vs. antiparallel alignment) can be measured, such that two distinct information states can be defined.

Note of course that the application of an externally applied magnetic field is not the only way for the MEJ to take advantage of reduced coercivity upon application of a potential difference. For example, the magnetization of the FM fixed layer can be used to impose a magnetization direction on the free layer when the free layer has a reduced coercivity. Moreover, an MEJ can be configured to receive a spin-transfer torque current when application of a voltage causes a reduction in the coercivity of the FM free layer. Generally, STT current is a spin-polarized current that can be used to facilitate the change of magnetization direction on a ferromagnetic layer. It can originate, for example, from a current passed directly through the MEJ device, such as due to leakage when a voltage is applied, or it can be created by other means, such as by spin-orbit-torques (e.g., Rashba or Spin-Hall Effects) when a current is passed along a metal line placed adjacent to the FM free layer. Accordingly, the spin orbit torque current can then help cause the FM free layer to adopt a particular magnetization direction, where the direction of the spin orbit torque determines the direction of magnetization. This configuration is advantageous over conventional STT-RAM configurations since the reduced coercivity of the FM free layer reduces the amount of current required to cause the FM free layer to adopt a particular magnetization direction, thereby making the device more energy efficient.

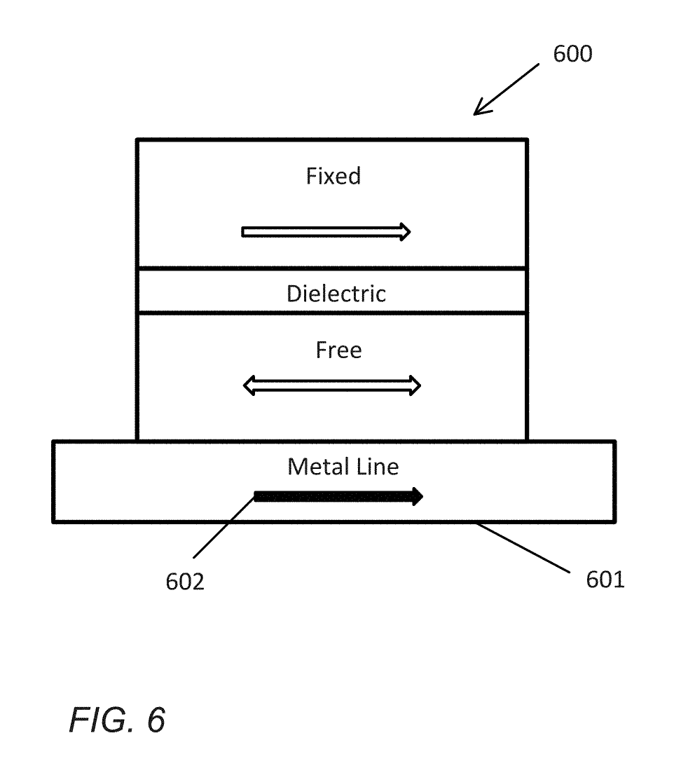

FIG. 6 depicts using a metal line disposed adjacent to an FM free layer to generate spin-orbit torques that can impose a magnetization direction change on the FM free layer. In particular, the MEJ 600 is similar to that seen in FIG. 1A, except that it further includes a metal line 601, whereby a current 602 can flow to induce spin-orbit torques, which can thereby help impose a magnetization direction change on the ferromagnetic free layer.

Additionally, in many instances, an MEJ cell can further take advantage of thermally assisted switching (“TAS”) principles. Generally, in accordance with TAS principles, heating up the MEJ during a writing process reduces the magnetic field required to induce switching. Thus, for instance, where STT is employed, even less current may be required to help impose a magnetization direction change on a free layer, particularly where VCMA principles have been utilized to reduce its coercivity.

Moreover, the switching of MEJs to achieve two information states can also be achieved using voltage pulses. In particular, if voltage pulses are imposed on the MEJ for a time period that is one-half of the precession of the magnetization of the free layer, then the magnetization may invert its direction. Using this technique, ultrafast switching times (e.g., below 1 ns) can be realized; moreover, using voltage pulses as opposed to a current, makes this technique more energetically efficient as compared to the precessional switching induced by STT currents, as is often used in STT-RAM. However, this technique is subject to the application of a precise pulse that is half the length of the precessional period of the magnetization layer. For instance, it has been observed that pulse durations in the range of 0.05 to 3 nanoseconds can reverse the magnetization direction. Additionally, the voltage pulse must be of suitable amplitude to cause the desired effect—e.g., reverse the direction of magnetization.

Based on this background, it can be seen that MEJs can confer numerous advantages relative to conventional MTJs. For example, they can be controlled using voltages of a single polarity—indeed, the '739 patent, incorporated by reference above, discusses using diodes, in lieu of transistors, as access devices to the MEJ, and this configuration is enabled because MEJs can be controlled using voltage sources of a single polarity.

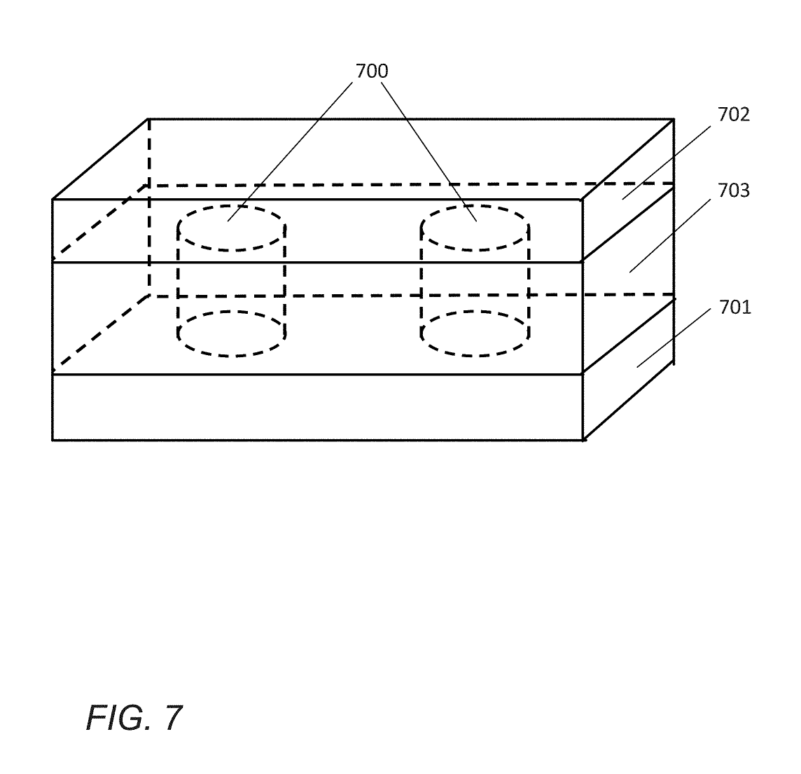

Note that while the above discussion largely regards the operation of single MEJs, it should of course be understood that in many instances, a plurality of MEJs are implemented together. For example, the '671 patent application discloses MeRAM configurations that include a plurality of MEJs disposed in a cross-bar architecture. It should be clear that MEJ systems can include a plurality of MEJs in accordance with embodiments of the invention. Where multiple MEJs are implemented, they can be separated by field insulation, and encapsulated by top and bottom layers. Thus, for example, FIG. 7 depicts the implementation of two MEJs that are housed within encapsulating layers and separated by field insulation. In particular, the MEJs 700 are encapsulated within a bottom layer 701 and a top layer 702. Field insulation 703 is implemented to isolate the MEJs and facilitate their respective operation. It should of course be appreciated that each of the top and bottom layers can include one or multiple layers of materials/structures. As can also be appreciated, the field insulation material can be any suitable material that functions to facilitate the operation of the MEJs in accordance with embodiments of the invention. While a certain configuration for the implementation of a plurality of MEJs has been illustrated and discussed, any suitable configuration that integrates a plurality of MEJs can be implemented in accordance with embodiments of the invention.

### Voltage Control of Oxidation Within Magnetic Heterostructures

Magnetic structures and devices in accordance with various embodiments of the invention can incorporate numerous types of materials to modify various magnetic properties of the structures. For example, Gd/GdO materials can be used to modify various magnetic properties of the heterostructures and layers, including but not limited to: saturation magnetization, steady-state magnetic orientation, magnetic strength, magnetic coercivity, antiferro/ferro/ferri/superpara/para/dia-magnetism, conductivity, voltage sensitivity of the voltage controlled magnetic anisotropy effect, perpendicular magnetic anisotropy, etc. In many embodiments, Gd/GdO materials are incorporated into a magnetic heterostructure between the electrodes, either in contact with the electrodes or within the stack of the heterostructure. In some embodiments, the Gd/GdO materials can be inserted into a single magnetic layer. In several embodiments, the Gd/GdO materials can be inserted within an MTJ. In further embodiments, the Gd/GdO materials are utilized in VMTJs. Gd/GdO materials can also be utilized within an MEJ.

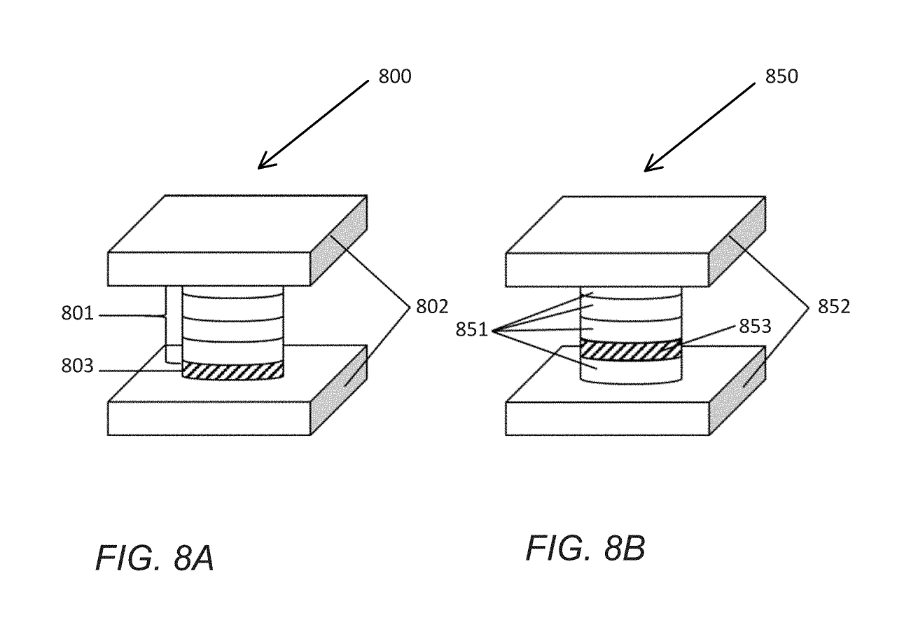

FIG. 8A and 8B conceptually illustrate schematics of magnetic heterostructures incorporating Gd/GdO materials in accordance with various embodiments of the invention. As shown, Gd/GdO materials can be inserted into a magnetic heterostructure or into a single magnetic layer in a number of different configurations. In the illustrative embodiments, the devices 800, 850 each include a magnetic heterostructure 801, 851 disposed between top and bottom electrodes 802, 852. The devices 800, 850 each further include at least one layer 803, 853 of Gd/GdO material disposed between the top and bottom electrodes 802, 852. In some embodiments, more than one layer of Gd/GdO material can be inserted within the device. As can readily be appreciated, the layer of Gd/GdO material can be inserted in a variety of configurations. In FIG. 8A, the Gd/GdO material layer is in contact with the bottom electrode. On the other hand, FIG. 8B shows the Gd/GdO material layer inserted within the stack of the heterostructure.

Although FIGS. 8A and 8B illustrate specific magnetic heterostructures incorporating Gd/GdO materials, any of a number of different structures and configurations can be implemented in accordance with various embodiments of the invention. For example, although FIGS. 8A and 8B show two configurations of where the layer of Gd/GdO material can be inserted, many other configurations can be implemented to achieve the desired effects in modifying the magnetic characteristics of the structure.

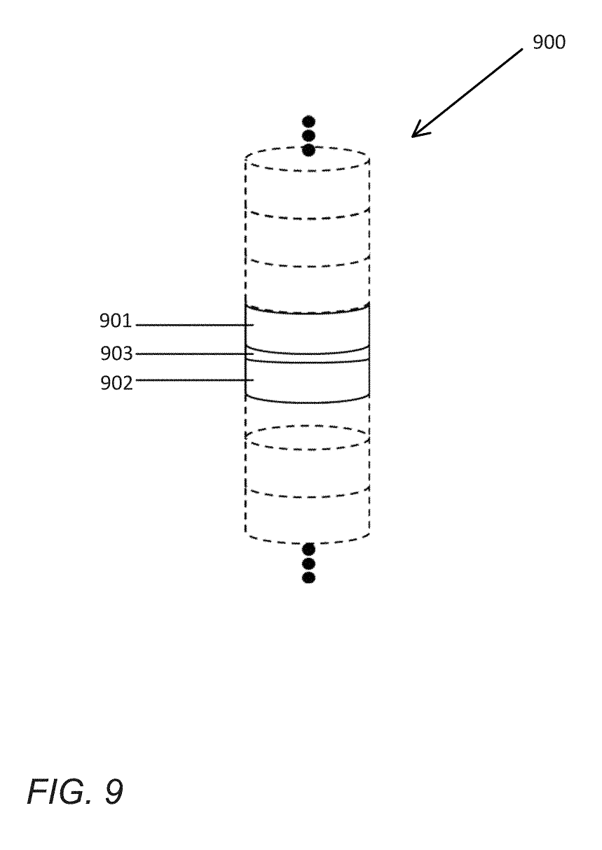

As discussed above, the Gd and/or GdO material layer can be inserted within a magnetic tunnel junction stack. FIG. 9 conceptually illustrates a schematic of a magnetic tunnel junction in accordance with an embodiment of the invention. FIG. 9 shows the base structure of a magnetic tunnel junction 900 with two layers 901, 902 of magnetic materials and a layer 903 of insulating material. In many embodiments, one of the two layers 901, 902 is usually designated the reference layer and the other is designated the free layer. The reference layer is typically interfaced with a pinning layer in order to pin its magnetic orientation. Examples of materials that may be used for magnetic layers (e.g., layers 901, 902) in accordance with embodiments can include, but are not limited to, CoFeB, CoFe, CoFeAl, CoB, FeB, CoMnSi, etc. Examples of materials typically used for insulating materials (e.g., layer 903) can include but are not limited to MgO, AlO, MgAlO, MgTiO, etc.

In conventional embodiments of magnetic tunnel junction structures, at the interface between the magnetic layers and insulating layer, specifically at the interface of layers 901, 903, and/or the interface of layers 903, 902, some of the magnetic material will see limited local oxidation which can change a variety of characteristics, such as but not limited to perpendicular magnetic anisotropy (“PMA”), magnetic coercivity, voltage sensitivity of the VCMA effect. By controlling the oxidation properties of such layers, the various characteristics can also be controlled. For example, over-oxidation of magnetic layer/insulating barrier interface can increase the voltage sensitivity of the VCMA effect—i.e., with same voltage applied across the magnetic layer/insulating barrier, the PMA of the magnetic layer changes more with over-oxidation. To control these characteristics, a Gd and/or GdO layer can be disposed within the layered structure. In some embodiments, Gd can attract O ions to form GdO. The O ions in Gd/GdO can move between the Gd/GdO layer and adjacent layers when a voltage bias is applied across the entire MTJ, thus allowing for the control of the oxygen concentration in adjacent layers.

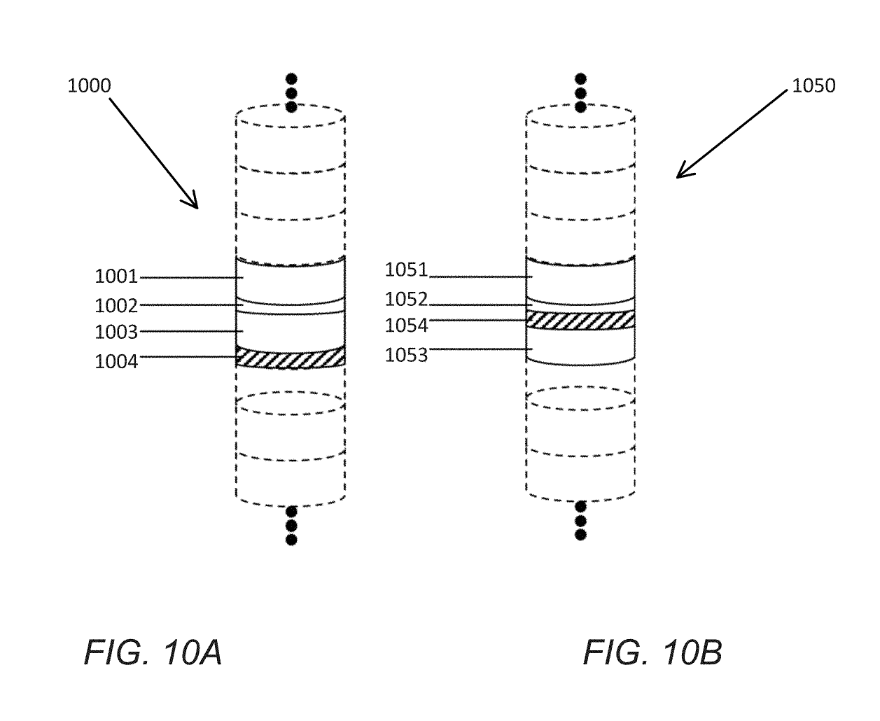

FIGS. 10A and 10B conceptually illustrate schematics of magnetic tunnel junctions incorporating Gd/GdO materials in accordance with various embodiments of the invention. As shown, the magnetic tunnel junctions 1000, 1050 each include a layer 1001, 1051 designated as the reference layer, a layer 1002, 1052 designated as the tunnel barrier (insulating layer), and a layer 1003, 1053 designated as the free layer. In the illustrative embodiments, layers 1004, 1054 are designated as where Gd, GdO, or a combination of Gd and GdO can be inserted into the MTJ structures 1000, 1050. Referring to FIG. 10A, a layer of GdO material can be inserted below the stack of reference/tunnel/free layers such that the oxygen concentration within the free layer can be controlled (increased) via the application of a voltage bias across the entire MTJ structure. In such embodiments, the process can be reversible. In embodiments in which Gd is utilized, oxygen concentration can be decreased via the application of a voltage bias across the entire MTJ structure, with the process being reversible. In embodiments in which a hybrid of Gd/GdO is utilized with Gd in contact with the free layer, or GdO/Gd with GdO in contact with the free layer, both an increase or a decrease in the oxygen concentration of the free layer is possible, with the process being reversible. Referring to FIG. 10B, where the GdO or Gd or any hybrid thereof is inserted within the stack of reference/tunnel/free layers, the oxygen concentration of both the free layer and tunnel layer may be increased and decreased based on the polarity of the voltage bias across the MTJ structure.

Although FIGS. 10A and 10B illustrate specific MTJ structures incorporating Gd/GdO materials, any of a number of different structures and configurations can be implemented in accordance with various embodiments of the invention. For example, although FIGS. 10A and 10B show two configurations of where the layer of Gd/GdO material can be inserted, many other configurations can be implemented to achieve the desired effects in modifying the magnetic characteristics of the structure.

### DOCTRINE OF EQUIVALENTS

While the above description contains many specific embodiments of the invention, these should not be construed as limitations on the scope of the invention, but rather as an example of one embodiment thereof. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A magnetic heterostructure comprising:
at least two electrodes;
a plurality of magnetic layers disposed between the at least two electrodes, wherein an insulating layer is disposed between at least two magnetic layers; and
at least one material layer disposed between the at least two electrodes, wherein the at least one material layer comprises a material selected from the group consisting of Gd, GdO, and hybrids thereof.

2. The magnetic heterostructure of claim 1, wherein the at least one material layer is disposed adjacent to at least one of the plurality of magnetic layers and the insulating layer.

3. The magnetic heterostructure of claim 1, wherein the at least one material layer is disposed between two of the plurality of magnetic layers and the insulating layer.

4. The magnetic heterostructure of claim 1, wherein the at least one material layer is configured to modify at least one magnetic property of the magnetic heterostructure.

5. The magnetic heterostructure of claim 4, wherein the at least one material layer is configured to control the oxygen concentration in adjacent layers in response to an applied electric field.

6. A magnetic tunnel junction comprising:
a plurality of magnetic layers, wherein an insulating layer is disposed between at least two of the magnetic layers, and wherein at least one of the magnetic layers is a reference layer and one of the magnetic layers is a free layer; and
at least one material layer comprising a material selected from the group consisting of Gd, GdO, and hybrids thereof.

7. The magnetic tunnel function of claim 6, wherein the at least one material layer is disposed on one or both sides of the reference layer.

8. The magnetic tunnel junction of claim 6, wherein the at least one material layer is disposed between the reference and insulating layers.

9. The magnetic tunnel junction of claim 6, wherein at least one of the magnetic layers is a pinning layer; and the at least one material layer is disposed between the reference layer and the pinning layer.

10. The magnetic tunnel junction of claim 6, wherein the at least one material layer is disposed adjacent to the free layer.

11. The magnetic tunnel junction of claim 6, wherein the at least one material layer is disposed between the free layer and the insulating layer.

12. The magnetic tunnel junction of claim 6, wherein the at least one material layer is configured to modify at least one magnetic property of the magnetic heterostructure.

13. The magnetic tunnel junction of claim 12, wherein the at least one material layer is configured to control the oxygen concentration in adjacent layers in response to an applied electric field.
